(19) United States
(12) Patent Application Publication
(10) Pub. No.: US 2014/0306284 A1
(43) Pub. Date: Oct. 16, 2014

(54) Semiconductor Device and Method for Producing the Same

(71) Applicant: Infineon Technologies Austria AG, Villach (AT)

(72) Inventors: Anton Mauder, Kolbermoor (DE); Franz Hirler, Isen (DE); Hans-Joachim Schulze, Taufkirchen (DE)

(21) Appl. No.: 13/861,823

(22) Filed: Apr. 12, 2013

(51) Int. Cl. H01L 29/10; H01L 29/66; H01L 21/223; H01L 29/78

(52) U.S. Cl. CPC H01L 29/105; H01L 29/7827; H01L 29/66666; H01L 21/2236
USPC 257/330; 438/270

(57) ABSTRACT

A trench gate MOS transistor is provided. It includes a semiconductor substrate with a trench including a gate electrode, a source region, a body contact region adjacent to a channel region, wherein the dopant concentration in the channel region varies in a lateral direction and has at least one minimal value in a direction from the gate electrode to the body contact region, which is distanced from the gate electrode. Further, a method for producing the transistor is provided.

### TECHNICAL FIELD

This specification refers to embodiments of methods for forming a semiconductor device. Furthermore, this specification refers to embodiments of semiconductor devices with a special channel doping, in particular a field effect semiconductor device having a special channel doping.

### BACKGROUND

Many functions of modern devices in automotive, consumer and industrial applications such as converting electrical energy and driving an electric motor or an electric machine rely on semiconductor devices, in particular on metal-oxide semiconductor (MOS) devices. Such MOS devices are often arranged in cells in a substrate and have to fulfill a number of properties. However, these properties may influence each other and sometimes require individual measures that may contradict each other. This is particularly relevant for properties such as threshold voltage, channel resistance, short circuit current, short channel effects, and resistance to latch-up.

In order to increase a device's resistance to the latch-up effect, it is required to achieve, in the case of n-channel transistors, a low-ohmic connection of the p-body, ideally extending under the whole source region, whereby only a channel region is excluded. On the other hand, for sufficient resistivity against short circuit and in order to achieve a low leakage current, it is advantageous to have a relatively highly doped body region extending far into the transistor. On the other hand, a vertically deep-reaching and high body doping causes a high threshold voltage and increases the channel resistance of the cell, due to the lower charge in the inversion layer. A further goal is the minimization of the gate-to-drain charge Q_{GD} and its distribution.

Particularly critical in this respect is the design of low-voltage power transistors with operating voltages below 100 V, requiring very low threshold voltages below about 3.5 V, for example in the regime up to 1 V. These may be developed, for example, with the purpose of supplying the switch from a 3.3 V power supply, in which case the channel resistance makes up a significant part of the overall resistance.

For these and other reasons there is a need for the present invention.

### SUMMARY

Embodiments of the invention include a trench gate MOS transistor, comprising a semiconductor substrate with a trench including a gate electrode, a source region, and a body contact region adjacent to a channel region. The dopant concentration in the channel region varies in a lateral direction and has at least one minimal value in a direction from the gate electrode to the body contact region, which is distanced from the gate electrode. In some embodiments, the dopant concentration decreases in a lateral direction from the gate electrode to the body contact region.

Other embodiments of the invention include methods of forming a vertical semiconductor. An example method comprises: providing a substrate, etching a trench for a gate electrode, providing a body contact region, providing a channel region located between the trench and the body contact region, applying a doping to implant a dopant into walls of the trench, and diffusing the dopant from the trench walls into the channel region in order to produce a laterally varying doping concentration in the channel region. In some embodiments, a doping profile of the channel region in a vertical direction is determined by the position and depth of the trench for the gate electrode, resulting in a self adjustment of the channel region with respect to the gate electrode.

These and other embodiments are illustrated in the attached drawings and described in detail below. Accordingly, those skilled in the art will recognize additional features and advantages of the present invention upon reading the following detailed description and upon viewing the accompanying drawings.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 schematically illustrates a vertical cross-section of a vertical semiconductor device according to one or more embodiments.

FIG. 2 schematically illustrates a vertical cross-section of a vertical semiconductor device according to one or more embodiments.

FIG. 3 schematically illustrates vertical cross-sections of vertical semiconductor devices according to one or more embodiments.

FIG. 4 schematically illustrates a vertical cross-section of a vertical semiconductor device according to one or more embodiments.

FIG. 5 schematically illustrates a method according to embodiments.

### DETAILED DESCRIPTION

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a first or main horizontal surface of a semiconductor substrate or body. This can be, for instance, the surface of a wafer or a die.

The term “vertical” as used in this specification is intended to describe an orientation which is substantially arranged perpendicular to the first surface, i.e., parallel to a normal direction with respect to the first surface of the semiconductor substrate or body.

In this specification, an n-doped material or region is referred to as having a first conductivity type, while a p-doped material or region is referred to as having a second conductivity type. It goes without saying that the semiconductor devices can be formed with opposite doping relations so that the first conductivity type can be p-doped and the second conductivity type can be n-doped. Furthermore, some Figures illustrate relative doping concentrations by indicating “−” or “+” next to the doping type. For example, “n⁻” means a doping concentration that is less than the doping concentration of an “n”-doping region while an “n⁺”-doping region has a larger doping concentration than the “n”-doping region. However, indicating the relative doping concentration does not mean that doping regions of the same relative doping concentration have to have the same absolute doping concentration unless otherwise stated. For example, two different n⁺ regions can have different absolute doping concentrations. The same applies, for example, to an n⁺ and a p⁺ region.

Specific embodiments described in this specification pertain to, without being limited thereto, field effect transistors, and in particular pertain to power field effect transistors. The term “field-effect,” as used in this specification, is intended to describe the electric-field mediated formation of a conductive “channel” of a first conductivity type and/or control of conductivity and/or shape of the channel in a semiconductor region of a second conductivity type, typically a body region of the second conductivity type. Due to the field-effect, a unipolar current path through the channel region is formed and/or controlled between a source region or emitter region of the first conductivity type and a drift region of the first conductivity type. The drift region may be in contact with a drain region or a collector region respectively. The drain region or the collector region is in ohmic contact with a drain or collector electrode. The source region or emitter region is in ohmic contact with a source or emitter electrode. Without applying an external voltage between the gate electrode and the source or emitter electrode, the ohmic current path between the source or emitter electrode and the drain or collector electrode through the semiconductor device is broken or at least high-ohmic in normally-off field effect devices. In normally-on field effect devices such as HEMTs (High Electron Mobility Transistors), depletion MOSFETs (Metal Oxide Field Effect Transistors) and normally-on JFETs (Junction-FETs), the current path between the source electrode and the drain electrode through the semiconductor device is typically low-ohmic without applying an external voltage between the gate electrode and the source or emitter electrode.

In the context of the present specification, the term “field-effect structure” is intended to describe a structure formed in a semiconductor substrate or semiconductor device having a gate electrode for forming and or shaping a conductive channel in the channel region. The gate electrode is at least insulated from the channel region by a dielectric region or dielectric layer.

In the context of the present specification, the terms “field plate” and “field electrode” are intended to describe an electrode that is arranged next to a semiconductor region, typically a drift region, insulated from the semiconductor region, and configured to expand a depleted portion in the semiconductor region by applying an appropriate voltage, typically a negative voltage relative to the semiconductor region for an n-type drift region.

The terms “depleted” and “completely depleted” are intended to describe that a semiconductor region comprises substantially no free charge carriers. Typically, insulated field plates are arranged close to pn-junctions formed, e.g., between a drift region and a body region. Accordingly, the blocking voltage of the pn-junction and the semiconductor device, respectively, may be increased. The dielectric layer or region that insulates the field plate from the drift region is in the following also referred to a field dielectric layer or field dielectric region. The gate electrode and the field plate may be on same electrical potential or on different electrical potential. The field plate may be on source or emitter potential. Furthermore, a portion of the gate electrode may be operated as field electrode.

Examples of dielectric materials for forming a dielectric region or dielectric layer between the gate electrode or a field plate and the drift region include, without being limited thereto, SiO₂, Si₃N₄, SiOₓN_{y}, Al₂O₃, ZrO₂, Ta₂O₅, TiO₂ and HfO₂, as well as mixtures and / or layers of these materials.

Embodiments described herein generally relate to trench transistors, wherein a doping of a channel region is produced by employing a plasma doping (PLAD), preferably through a wall of the trench. The transistor may, in some embodiments, optionally employ a field plate.

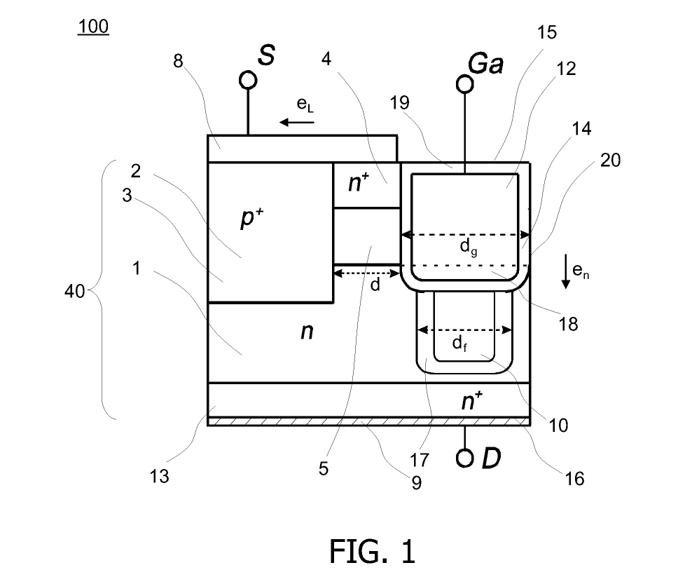

FIG. 1 illustrates an embodiment of a semiconductor device 100 in a section of a vertical cross-section. Typically, semiconductor device 100 is a power semiconductor device. In this case, the shown section typically corresponds to one of a plurality of unit cells in an active area of power semiconductor device 100. The semiconductor device 100 includes a semiconductor body 40 having a first or main horizontal surface 15 and a second or back surface 16 arranged opposite to the first surface 15. The normal direction eₙ of the first surface 15 is substantially parallel to, i.e. defines, the vertical dimension, and the direction e_{L} defines a horizontal or lateral dimension.

In the following, embodiments pertaining to semiconductor devices and manufacturing methods therefore, respectively, are explained mainly with reference to silicon (Si) semiconductor devices. Accordingly, a monocrystalline semiconductor region or layer is typically a monocrystalline Si-region or Si-layer. It should however be understood that the semiconductor body 40 can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa) or indium gallium arsenide phosphide (InGaAsP), and binary or ternary II-VI semiconductor materials such as cadmium telluride (CdTe) and mercury cadmium telluride (HgCdTe), to name a few. The above mentioned semiconductor materials are also referred to as homojunction semiconductor materials. When combining two different semiconductor materials, a heterojunction semiconductor material is formed. Examples of heterojunction semiconductor materials include, without being limited thereto, aluminum gallium nitride (AlGaN) and gallium nitride (GaN) or silicon-silicon carbide (SiₓC₁₋ₓ) and SiGe heterojunction semiconductor material. For power semiconductor applications, mainly Si, SiC and GaN materials are currently used. If the semiconductor body comprises a wide band gap material such as SiC or GaN, which has a high breakdown voltage and high critical avalanche field strength, respectively, the doping of the respective semiconductor regions can be chosen higher, which reduces the on-resistance Rₒₙ. It should further be understood that a semiconductor body may also include polycrystalline semiconductor regions. For example, a trench gate electrode or a field electrode arranged in an insulated trench may be formed by highly doped n-type of p-type polycrystalline semiconductor regions such as poly-Silicon. Accordingly, the term “exposing a semiconductor body” as used in this specification is intended to describe exposing a monocrystalline semiconductor region of the semiconductor body and/or exposing a polycrystalline semiconductor region arranged in the semiconductor body.

Referring again to FIG. 1, semiconductor body 40 includes an n-type first semiconductor region 1, a p-type second semiconductor region, in the following also called body contact region 2, which is arranged between first semiconductor region 1 and the main horizontal surface 15. The first semiconductor region 1 and the p-type body contact region 2 form a pn-junction. An n⁺-type source region 4, which extends to main surface 15, forms an additional pn-junction with the p-type body contact region 2. A channel region 5 is located, in a vertical direction, between n⁺-type source region 4 and the n-type first semiconductor region 1. In a horizontal direction, channel region 5 is located between a trench gate 12 and the body contact region 2.

The first semiconductor region 1, the p-type second semiconductor region, also called body contact region 2, the source region 4, and the channel region 5 may be shaped as bars which extend out of the drawing plane. The regions 2, 4, 5 may also be ring-shaped, or have the shape of a square with rounded corners when viewed from a top of the device 100. In this case, the structure shown in FIG. 1, and also the following figures corresponds to a respective simply connected semiconductor region.

In embodiments, the dopant concentration of the channel region 5 is produced independently from the dopant concentration in the body contact region 2 during manufacturing of the device 100. This is typically achieved by producing the dopant concentration in the channel region 5 by a different process than the doping of the body contact region 2. In embodiments, the doping of the channel region 5 is achieved by applying a plasma doping (PLAD). It is typically applied after the trench 20 for the gate electrode 12 has been produced, and after a gate oxide 14 has been applied to the walls of the trench 20. This is typically carried out before applying the material for gate electrode 12, which material typically includes polycrystalline silicon.

For applying the doping in the channel region 5 by a PLAD process, ions are implanted into the gate oxide 14 walls in trench 20. This is carried out by exposing the semiconductor body 40 with the trench 20 to a plasma of Ar, Kr, Xe, Ne or another noble gas or an inert gas. In a subsequent heating step, part of the ions implanted into the walls of the gate oxide 14 diffuse from the gate oxide 14 in the direction of the channel region 5, which is p-doped in this process. The parameters of the PLAD process and the subsequent heating step are chosen such that the resulting dopant concentration of the channel region 5 varies in a lateral direction e_{L}, i.e., parallel to semiconductor surface 15 in FIG. 1. More typically, the dopant concentration decreases in the direction e_{L} from the gate oxide 14 towards the body contact region 2. In this manner, it is possible to de-couple the doping and resulting dopant concentration of the channel region 5 from those of the body contact region 2. At the same time, a channel with a self-adjusted depth with respect to the gate electrode 12, respectively to gate oxide 14, is achieved. In embodiments, the doping profile of the channel region 5 in a vertical direction is determined by the position and depth of the trench 20 for the gate electrode, resulting in a self adjustment of the channel region 5 with respect to the gate electrode.

In embodiments, the resulting dopant concentration in the channel region 5 varies in a lateral direction e_{L} and has at least one minimal value in a direction from the gate electrode 12 to the body contact region 2. Thereby, the position of the minimum value is distanced from the gate oxide 14. The minimum value of the dopant concentration is typically smaller than 70%, more typically smaller than 50%, even more typically smaller than 20% of the maximum value of the dopant concentration in the channel region 5. While the concentration of the dopant decreases towards the body contact region 2 in the direction e_{L}, it is typically chosen to be high enough in order to achieve an ohmic connection of the channel region 5 to the body contact region 2.

Due to a parasitic segregation process during manufacturing, the maximum dopant concentration in the channel region 5 may not be located directly at the border region to the gate oxide 14, but may instead be slightly distanced from it. Hence, in a direction e_{L} from the gate oxide 14 to the body contact region 2, the dopant concentration in the channel region 5 first increases, and then decreases when proceeding further towards the body contact region 2 in direction e_{L}. However, the position of this local maximum is typically distanced by no more than 10% or no more than 20% of the distance d from the gate oxide 14, wherein d is the distance between gate oxide 14 and the body contact region 2. Hence, typically the maximum of the dopant concentration in the channel region 5 is located adjacent the gate electrode 12 and gate oxide 14.

Typically, the position of the minimum value of the dopant concentration in the channel region 5 is distanced from the gate oxide 14 by more than 70% of the distance d between gate oxide 14 and channel region 5, even more typically by more than 90% of distance d.

The characteristics of the dopant concentration, applied as described above, influence the threshold voltage of the semiconductor device 100. Further, as shown in FIG. 1, a semiconductor device 100 according to embodiments typically comprises a field plate 10. As shown in FIG. 1, the field plate 10 and the body contact region 2 reach further into the first semiconductor region 1 in a vertical direction eₙ than the channel region 5. Typically, the field plate extends more than 20% deeper, more typically more than 30% deeper into the semiconductor first region 1 than the channel region 5.

In embodiments, the body contact region 2 is typically doped more strongly than the channel region 5. As an effect, when the transistor blocks, there is no buildup of a space-charge region of any considerable width in the p-doped channel region 5. Effects that are caused by a dynamic reduction of the channel length, such as in case of short circuit and respective short circuit currents, are thus strongly reduced.

Moreover, a further advantageous effect of the structure 100 according to embodiments is that the distance between the channel region 5 and the more highly doped body contact region 2 may be designed to be smaller than in a structure with an identical dopant concentration in body contact region 2 and channel region 5. Thus, the device 100 according to embodiments has an improved robustness against the latchup effect. There are certain operation modes when the maximum blocking voltage of the device 100 is exceeded, e. g., when turning off an inductive load without providing a free wheeling circuit, and a load current is sustained by generation of pairs of electrons and holes in regions of high electric fields. Depending on the actual design of the transistor, the highest electric fields and thus the highest generation rates may occur, e. g., near the bottom of the body contact region 2 and/or near the lower part of the field plate 10. Holes produced during avalanche mode can thus move over a low-ohmic connection towards source contact 8. Consequently, the risk of triggering the parasitic npn-transistor with the n⁺ source is significantly reduced.

In further embodiments, the laterally varying dopant concentration in channel region 5 is produced differently to the manufacturing method described above. In these embodiments, a body contact region 2 is first produced, wherein the p-dopant concentration is higher than the concentration which would be necessary for achieving a desired threshold voltage. Subsequently, a compensating n-doping is applied via PLAD through the walls of trench 20 to channel region 5, i.e., through the gate oxide 14.

Generally, in some embodiments, the introduction of the doping of the channel region 5 via the walls of the trench 20 allows a realisation of the channel in a self-adjusted manner with respect to the trench gate 12. The gate oxide 14 in trench 20 thereby serves as a mask for the PLAD process, prior to the application of the gate 12. Alternatively, a vertical distance oxide 19 may be placed in a vertical direction above the gate oxide 14 and the field plate 10. Or in other words, the parts of the gate trench that are only covered by thin layers like, for example, the gate oxide 14, do not shield the doping of the channel region 5. The end of the channel region is therefore adjusted to the lower end of the later gate electrode 12, minimizing geometrical overlap and thus stray capacitances. On the other hand, a conductive path for carriers from the channel into the drift region 1 is ensured. The unwanted doping of semiconductor material below the gate trench 20 is ensured by the field plate 10 and the field electrode 17.

Thereby, in embodiments, the highly doped body contact region 2 is typically realized via a masked implantation, for example, by using ions of varying energy levels during implantation. Alternatively, in some embodiments, a second trench 3 for the body contact region 2 may be etched. Subsequently, the second trench is filled by adding to the walls of this trench, in various non-limiting examples, one or more of the following: polycrystalline silicon, boron silica glass (BSG), which may then be treated and activated by ion implantation or plasma doping (PLAD).

According to an embodiment, the bottom of the trench 20 may optionally be covered by an auxiliary layer 18 (delimited upwards by dashed line), essentially leaving open the trench sidewall to prevent the doping of the channel region 5 reaching deeper into the semiconductor device 100 in a vertical direction eₙ. This auxiliary layer 18 may consist of a polymer, such as a photo-resist, for example, and may be removed during the later process steps. In some embodiments, it may consist of a dielectric material, such as SiO₂, which may be only partially removed or may even remain at the bottom of the gate trench.

According to an embodiment, the doping of channel region 5 may also be achieved using tilted-ion implantation, in case in twin mode or quad mode, i. e. using implantation under different angles.

According to an embodiment, the doping of the channel region 5 may take place before finalizing the gate oxide 14. In one embodiment, a thin scatter layer, e. g., a scatter oxide, is covering the sidewall of the trench 20 when the doping of the channel region 5 is done. After optionally removing a part or all of the scatter layer, the gate oxide may be generated by thermal oxidation and/or deposition process.

According to an embodiment the channel region 5 may be doped with a second conductivity type leading, e. g., to an enhancement MOSFET. According to another embodiment, the channel region 5 may be doped with a first conductivity type leading, e. g., to a depletion MOSFET.

In embodiments, a first metallization 8 is arranged on parts of main horizontal surface 15. A second metallization 9 is arranged on back surface 16. The back surface 16 delimits a strongly doped contact zone 13 on the back side of the semiconductor body 40. Semiconductor device 100 includes a trench gate electrode 12 structure arranged in a deep trench 20. Accordingly, semiconductor device 100 may be operated as a vertical field effect semiconductor device which switches and/or controls a load current between the two metallizations 8, 9.

Semiconductor device 100 may form a MOSFET. In this case, drift region 1 is in ohmic connection with the second metallization 9 forming a drain electrode via an n⁺-type drain contact region 13. Further, first metallization 8 forms a source electrode 8 that is in ohmic connection with source region 4 and with p⁺-type body contact region 2. The doping concentrations of source region 4 and body contact region 2 are typically higher than the doping concentration of first semiconductor region 1 forming drift region 1.

In the context of the present specification, the terms “in ohmic contact”, “in electric contact”, “in contact”, “in ohmic connection”, and “electrically connected” are intended to describe that there is an ohmic electric connection or ohmic current path between two regions, portion or parts of a semiconductor devices, in particular a connection of low-ohmic resistance, even if no voltages are applied to the semiconductor device.

Semiconductor device 100 may also form an IGBT. In this case, a p⁺-type contact zone 13 of the semiconductor forms a collector region 13, which is arranged between drift region 1 and the second metallization 9, forming a collector electrode 9. Further, first metallization 8 forms an emitter electrode 8 which is in ohmic connection with a p⁺-type body contact region 2. Contact zone 13 may also include n-type and p-type portions so that semiconductor device 100 may be operated as an IGBT with integrated free-wheeling diode.

It goes without saying that the doping relations of the semiconductor regions may also be reversed.

For switching and/or controlling a load current between the two metallizations 8, 9, at least one trench gate electrode 12 is provided. In the exemplary embodiment illustrated in FIG. 1, the deep trench 20 extends from the main horizontal surface 15, past the source region 4, the channel region 5, and partially into the first semiconductor region 1. In other words, the deep trench 20 extends vertically below the pn-junction formed between the drift region 1 and the body contact region 2. The deep trench 20 is insulated from semiconductor body 40 by a thin dielectric layer 14 and includes a respective conductive region 12. The thin dielectric layer 14 is in the following also referred to as gate oxide 14 or gate oxide layer 14. At high enough voltage difference between body contact region 2 and the respective adjacent conductive regions 12, an inversion channel is formed in the channel region 5 along gate dielectric layer 14 between drift region 1 and source or emitter region 4. Accordingly, a load current may be switched and/or controlled. Typically, conductive region 12 forms a gate electrode 12 which is electrically connected to a gate metallization (not shown) and terminal Ga. Lower portions of conductive region 12 may in embodiments also form a field electrode 10 as shown in FIG. 1. In this case, the thin dielectric layer 14 is typically thickened in the respective lower trench portion, carrying the field electrode 10, to form a thicker field oxide.

According to an embodiment, the trench 20 is formed in an etching process and filled with a polycrystalline semiconductor material. This also facilitates manufacturing of semiconductor device 100. Depending on the doping type of the semiconductor regions, semiconductor device 100 may be operated as a MOSFET or an IGBT. The gate electrode 12 in FIG. 1 is located over a field electrode 10 surrounded by a field dielectric. But this is only an example. According to an embodiment, the width d_{g} of the trench 20 in a lateral direction e_{L} at the gate electrode may be the same or may be wider than the width d_{f} of the trench 20 in a lateral direction e_{L} at the field plate. According to another embodiment, the field electrode 12 and the field dielectric may be omitted so that also the lower part of the gate dielectric 14 at the bottom of the trench 20 is in direct contact with the drift region 1.

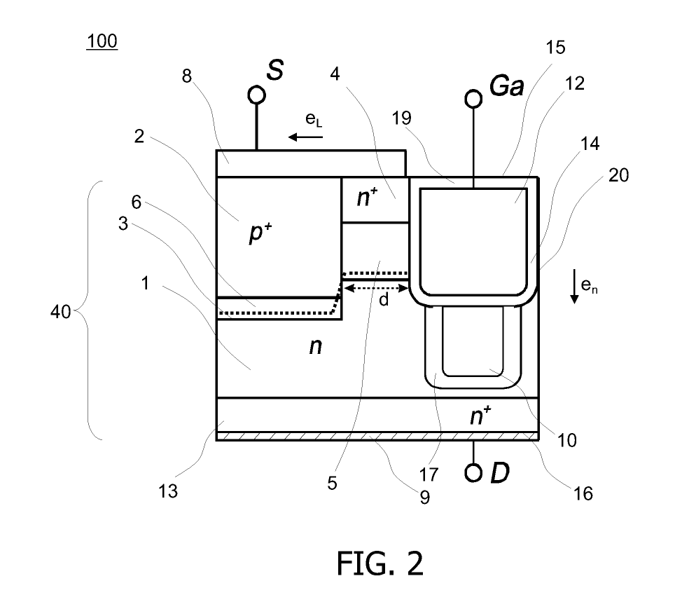

In FIG. 2, an embodiment based on the device of FIG. 1 is shown. Additionally, the dopant concentration of the body contact region 2 is also varied, in addition to the variation of the doping of the channel region 5 already described above. However, the dopant concentration of the body contact region is varied in a vertical direction eₙ, such that an additional body contact region 6 exists with a lower dopant concentration than the body contact region 2. The effect is that in the border region of zone 6 towards first semiconductor region 1 respectively drift region 1, the concentration of acceptors is lower, and the field stop is not fully depleted of mobile carriers or holes provided by the doping of zone 6 in the state of static blocking—for this case, the dashed line in FIG. 2 marks the end of the space charge region. Only at higher current densities, the space-charge region extends deeper into the body contact region 2, which increases the blocking voltage and leads to a stabilization of the characteristics in avalanche operation.

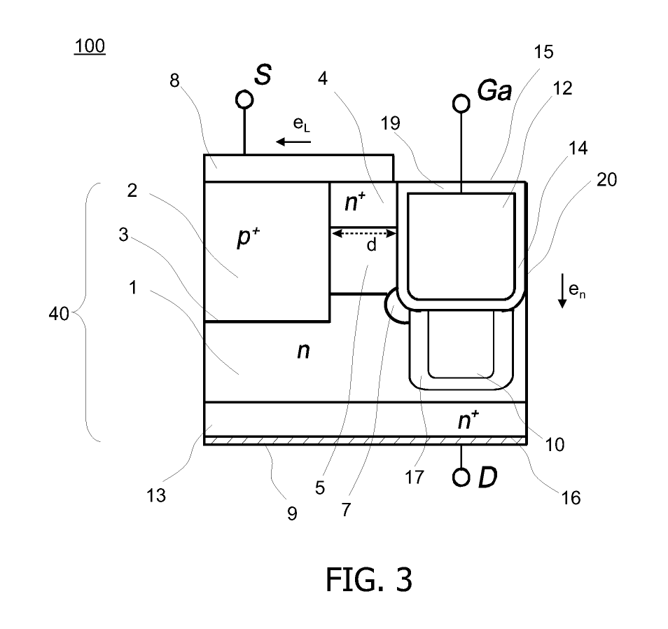

FIG. 3 shows a semiconductor device 100 according to embodiments. In the FIGS. 1 and 2, the channel region 5 should end in the vertical direction eₙ before the end of the gate electrode 12 is reached. In other words, there should be an overlap where the drift zone 1 is adjacent to the gate dielectric 14. However deviations in the process, e. g., diffusion or scattering during the doping process, may lead to the insertion of dopants from the channel region 5 to the drift zone 1, reducing the conductivity of the drift zone 1 close to the channel end. One additional topic is a very high current density of the electron current at the end of the inversion channel. This high current density has to spread to a more homogeneous current density towards the way to the contact zone 13. A high conductivity of the drift zone 1 close to the end of the inversion channel helps to disproportionately reduce the onstate resistance of the semiconductor device 100. Therein, additionally to the device 100 shown in FIG. 1, an n-doped channel connection zone 7 is provided at the end region of channel region 5 towards the trench 20, in the lower vertical section of channel region 5. As the p-doped channel region 5 is shielded in a blocking state of the transistor, the zone 7 may be applied with a higher n-doping. In embodiments the zone 7 is produced after back-etching the field oxide layer 17, so that it may reach deeper into the device 100 than the gate electrode 12. Without the channel connection zone 7, the resulting inversion channel in the channel region 5 might show a reduced conductivity at the end of channel region 5.

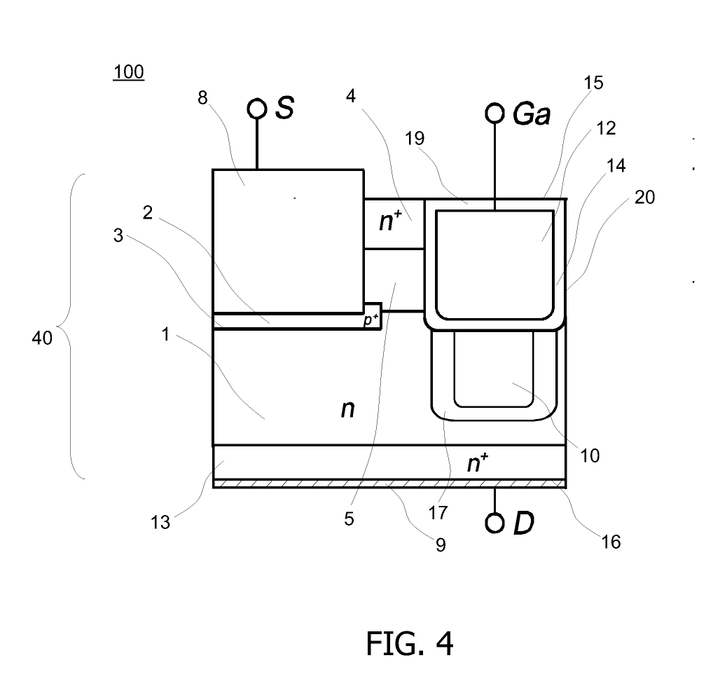

In FIG. 4, a further device 100 according to embodiments is shown. Therein, the body contact region 2 is implanted via a deep reaching contact hole 3, and subsequently annealed, respectively only lightly diffused. This embodiment may also be combined with the channel connection zone 7 shown in FIG. 3.

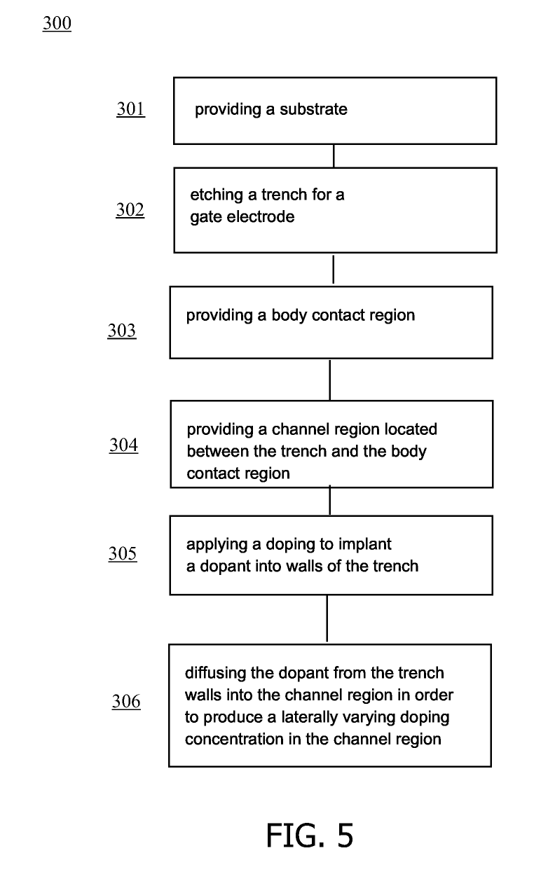

In FIG. 5, a method 300 for forming a vertical semiconductor according to embodiments is schematically shown. It comprises providing a substrate in a block 301, etching a trench for a gate electrode in a block 302, providing a body contact region in a block 303, providing a channel region located between the trench and the body contact region in a block 304, applying a doping to implant a dopant into walls of the trench in a block 305, and diffusing the dopant from the trench walls into the channel region in order to produce a laterally varying doping concentration in the channel region in a block 306. Preferably, the doping is a plasma doping.

The written description above uses specific embodiments to disclose the invention, including the best mode, and also to enable any person skilled in the art to make and use the invention. While the invention has been described in terms of various specific embodiments, those skilled in the art will recognize that the invention can be practiced with modification within the spirit and scope of the claims. Especially, mutually non-exclusive features of the embodiments described above may be combined with each other. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A trench gate MOS transistor, comprising:
a semiconductor substrate with a trench including a gate electrode,
a source region, and
a body contact region adjacent to a channel region,
wherein the dopant concentration in the channel region varies in a lateral direction and has at least one minimal value in a direction from the gate electrode to the body contact region, which is distanced from the gate electrode.

2. The trench gate transistor of claim 1, wherein the dopant concentration decreases in a lateral direction from the gate electrode to the body contact region.

3. The trench gate transistor of claim 1, wherein the minimum value of the dopant concentration is smaller than 20% of the maximum value of the dopant concentration in the channel region.

4. The transistor of claim 1, wherein the position of the minimum value of the dopant concentration in the channel region is distanced from the gate electrode by more than 70% of the mean distance d between the gate electrode and channel region.

5. The transistor of claim 1, wherein the channel region has an ohmic connection to the adjacent body contact region.

6. The transistor of claim 1, wherein the maximum of the dopant concentration in the channel region is located adjacent the gate electrode.

7. The transistor of claim 1, wherein the varying dopant concentration is produced by plasma doping (PLAD).

8. The transistor of claim 7, wherein the plasma doping is effected from a trench of the gate electrode.

9. The transistor of claim 1, further comprising a field plate or field electrode located adjacent the gate electrode.

10. The transistor of claim 9, wherein the field plate or field electrode is located vertically below the gate electrode.

11. The transistor of claim 10, wherein the field plate or field electrode extends at least 20% deeper in a vertical direction into the semiconductor substrate than the channel region.

12. The transistor of claim 1, wherein the body contact region extends, in a vertical direction, deeper into the semiconductor substrate than the channel region.

13. The transistor of claim 1, wherein the dopant concentration of the body contact region varies in a vertical direction.

14. The transistor of claim 13, wherein the dopant concentration decreases in a vertical direction.

15. The transistor of claim 1, wherein the channel region is basically p-doped, and comprises a zone with an n-dopant adjacent the gate electrode.

16. A method of forming a vertical semiconductor, comprising:
providing a substrate,
etching a trench for a gate electrode,
providing a body contact region,
providing a channel region located between the trench and the body contact region,
applying a doping to implant a dopant into walls of the trench,
diffusing the dopant from the trench walls into the channel region in order to produce a laterally varying doping concentration in the channel region.

17. The method of claim 16, wherein a doping profile of the channel region in a vertical direction is determined by the position and depth of the trench for the gate electrode, resulting in a self adjustment of the channel region with respect to the gate electrode.

18. The method of claim 16, wherein the doping is a plasma doping.

19. The method of claim 16, wherein the body contact region and the gate electrode extend into the substrate at least 20% deeper in a vertical direction than the channel region.

20. The method of claim 16, further comprising applying a vertically varying dopant concentration to the body contact region.

21. The method of claim 16, further comprising applying an n-doped region at the end of the channel region adjacent the gate electrode.

22. The method of claim 16, wherein the body contact region is implanted via a contact hole that reaches deeper into the substrate than the channel region.

23. A method for forming a trench gate field effect semiconductor device, comprising:
providing a semiconductor body comprising a main horizontal surface;
forming a body contact region;
forming a trench in the main horizontal surface;
forming a gate oxide layer in the trench;
applying a plasma doping to the semiconductor body in order to implant a dopant into trench walls;
heating the semiconductor body; an
filling the trench with a conductive material.
